(19) United States
(12) Patent Application Publication
(10) Pub. No.: US 2022/0208526 A1
(43) Pub. Date: Jun. 30, 2022

(54) PROCESS CHAMBER HAVING A TEMPERATURE MEASURING UNIT AND APPARATUS FOR PROCESSING A SUBSTRATE HAVING A TEMPERATURE MEASURING UNIT

(71) Applicant: Semes Co., Ltd., Cheonan-si (KR)

(72) Inventors: Doosoon KIM, Cheonan-si (KR); Sangmin MUN, Cheonan-si (KR)

(73) Assignee: Semes Co., Ltd., Cheonan-si (KR)

(21) Appl. No.: 17/456,180

(22) Filed: Nov. 23, 2021

(30) Foreign Application Priority Data
Dec. 30, 2020 (KR) 10-2020-0187431

(51) Int. Cl. H01J 37/32

(52) U.S. Cl. CPC H01J 37/32522; H01J 37/32532; H01J 37/3244

(57) ABSTRACT

An apparatus for processing a substrate may include an upper electrode, a gas distributing unit disposed under the upper electrode, a shower head disposed under the gas distributing unit, a temperature measuring unit including a first temperature sensor for measuring a temperature of the shower head, and a lower electrode disposed under the shower head. The first temperature sensor may pass through the upper electrode and the lower electrode and may make directly contact with the shower head.

### CROSS-REFERENCE TO RELATED APPLICATION

This application claims priority to Korean Patent Application No. 10-2020-0187431 filed on Dec. 30, 2020 in the Korean Intellectual Property Office (KIPO), the contents of which are herein incorporated by reference in its entirety.

### BACKGROUND

### 1. Field

Example embodiments of the invention relate to a process chamber having a temperature measuring unit and an apparatus for processing a substrate having a temperature measuring unit. More particularly, example embodiments of the invention relate to a process chamber having a temperature measuring unit capable of exactly measuring a process temperature through a shower head, and an apparatus for processing a substrate having a temperature measuring unit capable of exactly measuring a process temperature through a shower head.

### 2. Related Technology

An integrated circuit device including a semiconductor device or a display device including a flat panel display device may be usually manufactured using an apparatus for processing a substrate including various process chambers such as a deposition chamber, a sputtering chamber, an etching chamber, a cleaning chamber, a drying chamber, etc. Some of the process chambers can process a substrate utilizing a plasma wherein the plasma may be generated at a very high temperature and/or in a strong electric field.

The conventional apparatus for processing a substrate includes a temperature sensor which makes contact with a gas distributing device in the process chamber and measures the temperature of the plasma process performed on the substrate. However, the conventional temperature sensor contacts the gas distributing device for distributing a process gas in the process chamber so that the conventional temperature sensor may not exactly measure the temperature in the process chamber wherein the plasma process is performed. Therefore, the stability of the process performed on the substrate may be deteriorated and also the reliability of the integrated circuit device or the display device including such substrate may be reduced.

### SUMMARY

In one aspect of the invention, there is provided a process chamber including a temperature measuring unit capable of exactly measuring a process temperature through a shower head.

In another aspect of the invention, there is provided an apparatus for processing a substrate including a temperature measuring unit capable of exactly measuring a process temperature through a shower head.

According to one aspect of the invention, there is provided a process chamber including a gas distributing unit, a shower head disposed under the gas distributing unit and a temperature measuring unit contacting shower head. The temperature measuring unit may include a first temperature sensor for measuring a temperature of the shower head

In example embodiments, the process chamber may additionally include an upper electrode disposed on the gas distributing unit and a lower electrode opposed to the upper electrode. In this case, the first temperature sensor may pass through the upper electrode and the lower electrode and may make contact with the shower head.

In example embodiments, a first receiving hole for receiving the first temperature sensor may be provided through the upper electrode and the gas distributing unit.

In some example embodiments, the shower head may include a receiving groove for receiving an end portion of the first temperature sensor.

In other example embodiments, the first temperature sensor may contact a coupling member for coupling the gas distributing unit to the shower head. For example, the coupling member may have a bolt structure.

In example embodiments, the temperature measuring unit may include a second temperature sensor for measuring a temperature of the gas distributing unit. The second temperature sensor may pass through the upper electrode and may make contact with the gas distributing unit.

In example embodiments, a second receiving hole for receiving the second temperature sensor may be provided through the upper electrode.

In example embodiments, the first temperature sensor may include a thermocouple sensor. Alternatively, the first temperature sensor may include a fiber sensor.

According to another aspect of the invention, there is provided an apparatus for processing a substrate including an upper electrode, a gas distributing unit disposed under the upper electrode, a shower head disposed under the gas distributing unit, a temperature measuring unit contacting shower head and including a first temperature sensor for measuring a temperature of the shower head, and a lower electrode disposed under the shower head.

In example embodiments, the first temperature sensor may pass through the upper electrode and the lower electrode and may make directly contact with the shower head.

In example embodiments, a first receiving hole for receiving the first temperature sensor may be provided through the upper electrode and the gas distributing unit.

In some example embodiments, the shower head may include a receiving groove for receiving an end portion of the first temperature sensor.

In other example embodiments, the first temperature sensor may contact a coupling member for coupling the gas distributing unit to the shower head.

In example embodiments, the temperature measuring unit may include a second temperature sensor for measuring a temperature of the gas distributing unit. The second temperature sensor may pass through the upper electrode and may make contact with the gas distributing unit.

According to still another aspect of the invention, there is provided an apparatus for processing a substrate including a process chamber having a processing space in which a plasma process is performed. The apparatus for processing a substrate may include an upper electrode disposed in the processing space, a gas distributing unit disposed under the upper electrode; a shower head disposed under the gas distributing unit, a temperature measuring unit including a first temperature sensor for measuring a temperature of the shower head and a second temperature sensor for measuring a temperature of the gas distributing unit, and a lower electrode disposed under the shower head. The first temperature sensor may directly contact the shower head.

In example embodiments, the first temperature sensor may pass through the upper electrode and the lower electrode and may make directly contact with the shower head.

In some example embodiments, the shower head may include a receiving groove for receiving an end portion of the first temperature sensor.

In other example embodiments, the first temperature sensor may contact a coupling member for coupling the gas distributing unit to the shower head.

According to example embodiments of the invention, the temperature measuring unit including the temperature sensor which may directly contact the shower head such that temperature measuring unit may exactly measure the temperatures of processes performed in a processing space. Accordingly, the stabilities of the processes performed on the substrate may be enhanced using the apparatus for processing a substrate including the temperature measuring unit. Further, the apparatus for processing a substrate including the temperature measuring unit may improve the reliability of the integrated circuit device including the semiconductor device or the display device including the flat panel display device.

### BRIEF DESCRIPTION OF THE DRAWINGS

Example embodiments will be more clearly understood from the following detailed description taken in conjunction with the accompanying drawing. The following figures represent non-limiting, example embodiments as described herein.

FIG. 1 is a plane view illustrating an apparatus for processing a substrate in accordance with example embodiments of the invention.

FIG. 2 is a cross-sectional view illustrating an apparatus for processing a substrate having a temperature measuring unit in accordance with example embodiments of the invention.

FIG. 3 is an enlarged cross-sectional view illustrating the apparatus for processing a substrate having the temperature measuring unit of FIG. 2.

FIG. 4 is a perspective view illustrating a temperature sensor of a temperature measuring unit in accordance with example embodiments of the invention.

FIG. 5 is an enlarged cross-sectional view illustrating an apparatus for processing a substrate having a temperature measuring unit in accordance with some example embodiments of the invention.

FIG. 6 is a cross-sectional view illustrating an apparatus for processing a substrate having a temperature measuring unit in accordance with other example embodiments of the invention.

### DESCRIPTION OF EMBODIMENTS

Various embodiments will be described more fully hereinafter with reference to the accompanying drawings, in which some embodiments are shown. The invention may, however, be embodied in many different forms and should not be construed as limited to the embodiments set forth herein. Rather, these embodiments are provided so that this description will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (for example, rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include a plurality of forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the face through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the invention will be described in detail with reference to the accompanying drawings. Like elements or components can be indicated by like reference numerals throughout the drawings, and the repeated explanations of like elements or components may be omitted.

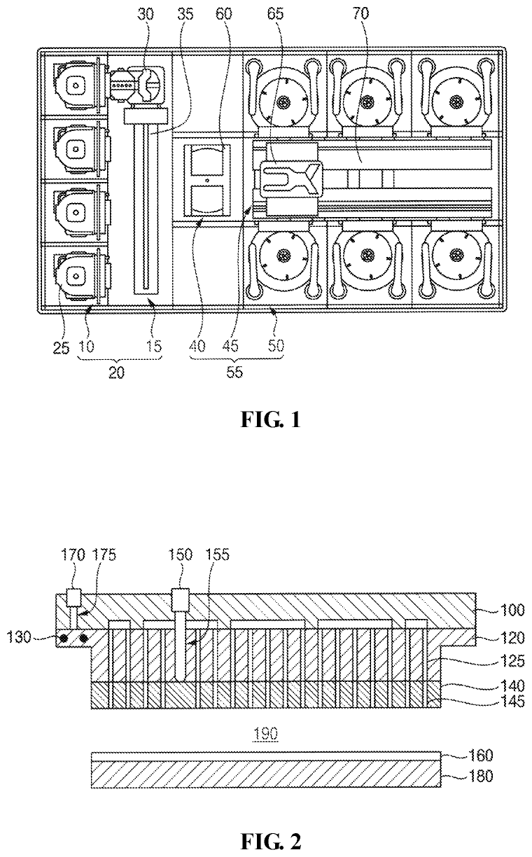

FIG. 1 is a plane view illustrating an apparatus for processing a substrate in accordance with example embodiments of the invention.

Referring to FIG. 1, the apparatus for processing a substrate may include an index module 20 and a processing module 55.

The index module 20 may transfer a substrate into the processing module 55 from an outside. The processing module 55 may perform predetermined processes on the substrate placed therein. Here, the substrate may be processed to manufacture an integrated circuit device or a display device.

In example embodiments, the index module 20 may include a load lock chamber 10 and a transferring frame 15. A carrier 25 for accommodating the substrate may be loaded in the load lock chamber 10. For example, a front opening unified pod (FOUP) may be used as the carrier 25. Additionally, the carrier 25 may be transferred into the load lock chamber 10 from the outside or from the load lock chamber 10 to the outside using an overhead transfer (OHT).

The transferring frame 15 may transfer the substrate between the processing module 55 and the carrier 25 loaded in the load lock chamber 10. The transferring frame 15 may include an index robot 30 and an index rail 36. The index robot 30 may move along the index rail 35 and may transfer the substrate between the index module 20 and the processing module 55. For example, the index robot 30 may transfer the substrate between the carrier 25 and a buffer slot 60 while the index robot 30 moves on the index rail 35.

As illustrated in FIG. 1, the processing module 55 may perform the predetermined processes including, but not limited to, a deposition process, an etching process, a sputtering process, a coating process, an exposure process, a developing process, a cleaning process, or a drying process, on the substrate. The processing module 55 may include a buffer chamber 40, a transfer chamber 45, a process chamber 50, a control unit (not illustrated), etc.

The substrate transferred between the index module 20 and the processing module 55 may be temporarily accommodated in the buffer chamber 40. The buffer chamber 40 may include the buffer slot 60 on which the substrate is placed. For example, the buffer chamber 40 may include a plurality of buffer slots 60, and thus a plurality of substrates may be received in the buffer chamber 40.

The transfer chamber 45 may transfer the substrate between the buffer chamber 40 and the process chamber 50. The transfer chamber 45 may include a transferring robot 65 and a transferring rail 70. The transferring robot 65 may move along the transferring rail 70 such that the transferring robot 65 may transfer the substrate between the buffer chamber 40 and the process chamber 50. For example, the transferring robot 65 may transfer the substrate placed on the buffer slot 60 into the process chamber 50 while the transferring robot 65 moves on the transferring rail 70.

The apparatus for processing a substrate may include a plurality of process chambers 50. The plurality of process chambers 50 may perform various processes of manufacturing an integrated circuit device including a semiconductor device or a display device including a flat panel display device. For example, the process chambers 50 may include, but not limited to, an etching chamber, a deposition chamber, a sputtering chamber, a coating chamber, an exposure chamber, a developing chamber, a cleaning chamber, a drying chamber, etc.

In example embodiments, the process chamber 50 may include a plasma processing chamber which may process the substrate using a plasma. In this case, the process chamber 50 may include, as illustrated in FIG. 2, a processing space 190, an upper electrode 100, a gas distributing unit 120, a heater 130, a shower head 140, a supporting unit 160, a lower electrode 180, a temperature measuring unit, etc.

FIG. 2 is a cross-sectional view illustrating an apparatus for processing a substrate having a temperature measuring unit in accordance with example embodiments of the invention. FIG. 3 is an enlarged cross-sectional view illustrating the apparatus for processing a substrate having the temperature measuring unit of FIG. 2.

Referring to FIG. 2 and FIG. 3, the supporting unit 160 may be disposed in the processing space 190 such that the supporting unit 160 may hold a substrate (not illustrated) placed thereon. For example, the supporting unit 160 may include an electrostatic chuck which may hold the substrate by an electrostatic force. Alternatively, the supporting unit 160 may support the substrate by clamping the substrate.

The lower electrode 180 may support the supporting unit 160 on which the substrate is placed. The lower electrode 180 may be disposed under the supporting unit 160 and may be coupled to the supporting unit 160. The lower electrode 180 may be electrically connected to a high frequency power source (not illustrated) for applying a high frequency bias power to the lower electrode 180.

The upper electrode 100 may be disposed to be substantially opposed to the lower electrode 180 centering around the processing space 190. The upper electrode 100 may be electrically connected to a separate high frequency power source (not illustrated) for applying a high frequency bias power to the upper electrode 100. Therefore, an electric field may be generated in the processing space 190 between the lower electrode 180 and the upper electrode 100 so as to generate the plasma from a process gas.

The gas distributing unit 120 may be disposed under the upper electrode 100. The gas distributing unit 120 may include a plurality of distributing holes 125. The process gas may be introduced into the gas distributing unit 120 from an outer gas source for generating the plasma in the processing space 190. For example, the process gas may include one kind of gas or more than two kinds of gases depending on process conditions. Further, the heater 130 may be provided in the gas distributing unit 120 for heating the process gas to a desired temperature. Although it is not illustrated, a power may be electrically connected to the heater 130 for applying a power to the heater 130.

The shower head 140 may be disposed under the gas distributing unit 120. For example, the shower head 140 may have a circular plate shape. A plurality of through holes 145 may be provided through the shower head 140. The process gas may be introduced into the processing space 190 through the plurality of distributing holes 125 of the gas distributing unit 120 and the plurality of through holes 145 of the shower head 140.

The temperature measuring unit may include a first temperature sensor 150 and a second temperature sensor 170. In this case, the first temperature sensor 150 may measure the temperature of the shower head 140 and the second temperature sensor 170 may measure the temperature of the gas distributing unit 120. The first temperature sensor 150 may make contact with the shower head 140. Further, the second temperature sensor 170 may make contact with the gas distributing unit 120 through the upper electrode 100. For example, the bottom face of the first temperature sensor 150 may contact the upper face of the shower head 140 and the bottom face of the second temperature sensor 170 may contact the upper face of the gas distributing unit 120.

In example embodiments, the first temperature sensor 150 may pass though the upper electrode 100 and the gas distributing unit 120, and then may directly contact the shower head 140. Here, a first receiving hole 155 may be provided through the upper electrode 100 and the gas distributing unit 120 through which the first temperature sensor 150 may be inserted. Additionally, the second temperature sensor 170 may pass through the upper electrode 100, and then may directly contact the gas distributing unit 120. To this end, a second receiving hole 175 may be provided through the upper electrode 100 through which the second temperature sensor 170 may be inserted. In this case, the second temperature sensor 170 may make contact with a portion of the gas distributing unit 120 adjacent to the heater 130.

In some example embodiments, the temperature measuring unit may include only the first temperature sensor 150 which may directly contact the shower head 140.

The conventional apparatus for processing a substrate includes only a temperature sensor contacting a gas distributing device disposed in a plasma processing chamber. The conventional temperature sensor can measure the process temperature of the plasma process performed on a substrate in the plasma processing chamber. However, the conventional temperature sensor makes contact with the gas distributing device for distributing a process gas so that the process temperature of the plasma process performed in the processing space is not be exactly measured. Thus, the stability of the plasma process may be reduced when the plasma process is executed using the conventional temperature sensor. For example, the plasma process may not be performed on the substrate at a desired temperature in the processing chamber. Further, when an integrated circuit device or a display device is manufactured using the apparatus for processing a substrate having the above configuration, the reliability of the integrated circuit device or the display device may be deteriorated.

According to example embodiments, the temperature measuring unit may include the first temperature sensor 150 which can directly contact the shower head 140 such that the first temperature sensor 150 may directly measure the temperature of the shower head 140. Since the first temperature sensor 150 may measure the temperature of the shower head 140 directly contacting the plasma generated in the processing space 190, the temperature measuring unit may exactly measure the temperature of the plasma process performed on the substrate in the processing space 190. Further, the temperature measuring unit may include the second temperature sensor 170 which can directly contact the gas distributing unit 120 so that the temperature measuring unit may more precisely measure the temperature of the plasma process performed on the substrate. Accordingly, the stability of the plasma process may be improved using the apparatus for processing a substrate including the temperature measuring unit. Moreover, the integrated circuit device or the display device may ensure enhanced reliability using the apparatus for processing a substrate including the temperature measuring unit.

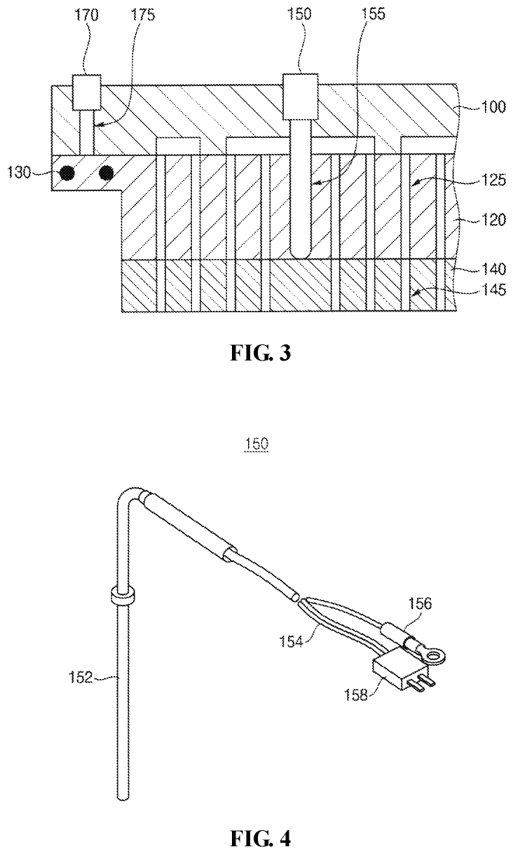

FIG. 4 is a perspective view illustrating the temperature sensor of the temperature measuring unit in accordance with example embodiments of the invention.

Referring to FIG. 4, the first temperature sensor 150 of the temperature measuring unit may include a thermocouple sensor 152, a sensor cable 154, a ground cable 156 and a connector 158.

In example embodiments, the thermocouple sensor 152 may directly contact the shower head 140. The thermocouple sensor 152 may be electrically connected to a power source (not illustrated) through the sensor cable 154 and the connector 158. While the temperature measuring unit measures the temperature of the shower head 140, the first temperature sensor 150 may be grounded through the ground cable 156.

FIG. 4 illustrates the first temperature sensor 150 including the thermocouple sensor 152, however, the first temperature sensor 150 may include a fiber sensor.

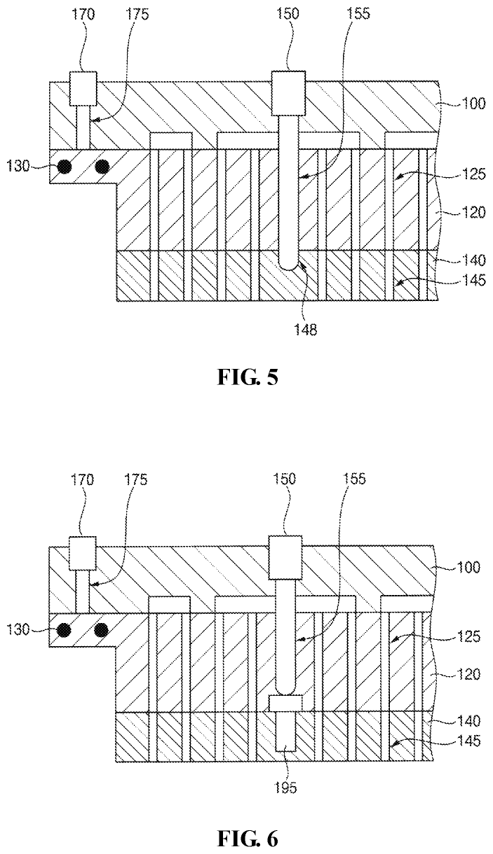

FIG. 5 is an enlarged cross-sectional view illustrating an apparatus for processing a substrate having a temperature measuring unit in accordance with some example embodiments of the invention.

As illustrated in FIG. 5, the temperature measuring unit according to some example embodiments may include a first temperature sensor 150 and a second temperature sensor 170. In this case, the first temperature sensor 150 may directly contact the shower head 140. A receiving groove 148 for receiving an end portion of the first temperature sensor 150 may be provided on the shower head 140. The first temperature sensor 150 may be inserted in the receiving groove 148 through the upper electrode 100 and the gas distributing unit 120 such that the first temperature sensor 150 may be directly contacted with the shower head 140. Such first temperature sensor 150 may exactly measure the temperature of the shower head 140, and thus the temperature measuring unit may exactly measure the temperature of the plasma process performed on the substrate in the processing space 190.

FIG. 6 is a cross-sectional view illustrating an apparatus for processing a substrate having a temperature measuring unit in accordance with other example embodiments of the invention.

Referring to FIG. 6, the temperature measuring unit according to other example embodiments may include a first temperature sensor 150 and a second temperature sensor 170. The first temperature sensor 150 may directly contact a coupling member 195 for the coupling the gas distributing unit 120 to the shower head 140. For example, the coupling member 195 may have a bolt structure and the bottom face of the first temperature sensor 150 may make contact with the upper face of the coupling member 195. Therefore, the temperature measuring unit including such first temperature sensor 150 may exactly measure the temperature of the plasma process performed on the substrate in the processing space 190.

According to example embodiments of the invention, the temperature measuring unit including the temperature sensor capable of directly contact the shower head may exactly measure the temperatures of the processes performed on the substrate in the processing space. Therefore, the stability of the process performed on the substrate may be enhanced using the apparatus for processing a substrate including the temperature measuring unit. Further, the apparatus for processing a substrate including the temperature measuring unit may ensure the improved reliability of the integrated circuit device including the semiconductor device or the display device including the flat panel display device.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A process chamber comprising:
a gas distributing unit;
a shower head disposed under the gas distributing unit; and
a temperature measuring unit contacting shower head, wherein the temperature measuring unit includes a first temperature sensor for measuring a temperature of the shower head.

2. The process chamber of claim 1, further comprising an upper electrode disposed on the gas distributing unit and a lower electrode opposed to the upper electrode, wherein the first temperature sensor passes through the upper electrode and the lower electrode and makes contact with the shower head.

3. The process chamber of claim 2, wherein a first receiving hole for receiving the first temperature sensor is provided through the upper electrode and the gas distributing unit.

4. The process chamber of claim 2, wherein the shower head includes a receiving groove for receiving an end portion of the first temperature sensor.

5. The process chamber of claim 2, wherein the first temperature sensor contacts a coupling member for coupling the gas distributing unit to the shower head.

6. The process chamber of claim 5, wherein the coupling member has a bolt structure.

7. The process chamber of claim 2, wherein the temperature measuring unit includes a second temperature sensor for measuring a temperature of the gas distributing unit, and the second temperature sensor passes through the upper electrode and makes contact with the gas distributing unit.

8. The process chamber of claim 7, wherein a second receiving hole for receiving the second temperature sensor is provided through the upper electrode.

9. The process chamber of claim 1, wherein the first temperature sensor includes a thermocouple sensor.

10. The process chamber of claim 1, wherein the first temperature sensor includes a fiber sensor.

11. An apparatus for processing a substrate, which comprises:
an upper electrode;
a gas distributing unit disposed under the upper electrode;
a shower head disposed under the gas distributing unit;
a temperature measuring unit contacting shower head, the temperature measuring unit including a first temperature sensor for measuring a temperature of the shower head; and
a lower electrode disposed under the shower head.

12. The apparatus for processing a substrate of claim 11, wherein the first temperature sensor passes through the upper electrode and the lower electrode and makes directly contact with the shower head.

13. The apparatus for processing a substrate of claim 12, wherein a first receiving hole for receiving the first temperature sensor is provided through the upper electrode and the gas distributing unit.

14. The apparatus for processing a substrate of claim 12, wherein the shower head includes a receiving groove for receiving an end portion of the first temperature sensor.

15. The apparatus for processing a substrate of claim 12, wherein the first temperature sensor contacts a coupling member for coupling the gas distributing unit to the shower head.

16. The apparatus for processing a substrate of claim 12, wherein the temperature measuring unit includes a second temperature sensor for measuring a temperature of the gas distributing unit, and the second temperature sensor passes through the upper electrode and makes contact with the gas distributing unit.

17. An apparatus for processing a substrate including a process chamber having a processing space in which a plasma process is performed, which comprises:
an upper electrode disposed in the processing space;
a gas distributing unit disposed under the upper electrode;
a shower head disposed under the gas distributing unit;
a temperature measuring unit including a first temperature sensor for measuring a temperature of the shower head and a second temperature sensor for measuring a temperature of the gas distributing unit; and
a lower electrode disposed under the shower head,
wherein the first temperature sensor directly contacts the shower head.

18. The apparatus for processing a substrate of claim 17, wherein the first temperature sensor passes through the upper electrode and the lower electrode and makes directly contact with the shower head.

19. The apparatus for processing a substrate of claim 17, wherein the shower head includes a receiving groove for receiving an end portion of the first temperature sensor.

20. The apparatus for processing a substrate of claim 17, wherein the first temperature sensor contacts a coupling member for coupling the gas distributing unit to the shower head.
